(19) United States
(12) Patent Application Publication
(10) Pub. No.: US 2001/0019141 A1
(43) Pub. Date: Sep. 6, 2001

(54) Semiconductor device with capacitive element and method of forming the same

(75) Inventor: Seiichi Takahashi, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/774,041

(22) Filed: Jan. 31, 2001

(30) Foreign Application Priority Data
Feb. 2, 2000 (JP) 2000-025069

(51) Int. Cl. H01L 21/00

(52) U.S. Cl. 257/295; 438/3; 438/240; 438/253; 438/622; 257/306; 257/310

(57) ABSTRACT

The present invention provides a semiconductor device having at least a multilevel metal interconnection structure, at least a capacitor which lies over the multilevel metal interconnection structure, and an inter-layer insulator under the capacitor and over the multilevel metal interconnection structure for isolating the multilevel metal interconnection structure form the capacitor, wherein at least an anti-oxidizing film preventing penetration of oxygen is provided in the inter-layer insulator, so that the anti-oxidizing film lies covering the multilevel metal interconnection structure and under the capacitor.

### BACKGROUND OF THE INVENTION

The present invention relates to a semiconductor device with a capacitive element and a method of forming the same, and more particularly to a semiconductor device with a capacitive element having a ferroelectric capacitive element as a capacitive dielectric film.

In recent years, a ferroelectric memory utilizing a ferroelectric capacitive film such as a ceramic thin film has been on the active development. The ferroelectric memory is provided with a selecting transistor. A capacitor is also provided which is connected to one of diffusion regions of the switching transistor, wherein the capacitor serves as a memory cell for storing informations. The ferroelectric capacitor uses a ferroelectric thin film such as PZT as a capacitive dielectric. Non-volatile informations may be stored by polarizing the ferroelectric. The ferroelectric has electrical polarity characteristics, wherein an application of an electric field to the ferroelectric causes an inversion of the polarity direction. If the direction of the applied electric field to the ferroelectric is changed from one direction to the opposite direction, then the polarization is caused by a hysteresis characteristics of the ferroelectric. Switching the voltage polarity cause plus and minus charges on the surface of the ferroelectric film. After the voltage application has been discontinued, then the pulse or minus charges remain on the surface of the ferroelectric film. These states correspond to the binary digit states, for example, 0 and 1.

FIG. 1 is a fragmentary cross sectional elevation view illustrative of a conventional semiconductor device having a capacitive element. The conventional semiconductor device may be formed as follows. A field oxide film is selectively formed on a surface of a semiconductor substrate 100 to form a device region of the semiconductor substrate 100. A plurality of transistor is formed on the device region of the semiconductor substrate 100, wherein diffusion regions 106 of the transistors are selectively formed in upper regions of the semiconductor substrate 100. A first level inter-layer insulator 103 is then formed which extends over the semiconductor substrate 100, so that the plural transistors formed in the semiconductor substrate 100 are covered by the first level inter-layer insulator 103. First level via holes are formed in the first level inter-layer insulator 103, so that the first level via holes are positioned over the diffusion regions of the plural transistors. First level metal contact plugs 107 are formed in the first level via holes, so that the bottoms of the first level metal contact plugs 107 are directly contact with the diffusion regions 106 of the transistors. First level interconnections 101 are formed over the top surface of the first level inter-layer insulator 103, so that the first level interconnections 101 are in contact directly with the tops of the first level metal contact plugs 107, whereby the first level interconnections 101 are electrically connected through the first level metal contact plugs 107 to the diffusion regions 106. A second level inter-layer insulator 104 is then formed which extends over the top surface of the first level inter-layer insulator 103 and also over the first level interconnections 101. Second level via holes are formed in the second level inter-layer insulator 104, so that the second level via holes are positioned over some of the first level interconnections 101. Second level metal contact plugs 108 are formed in the second level via holes, so that the bottoms of the second level metal contact plugs 108 are directly contact with the tops of the first level interconnections 101. Furthermore, second level interconnections 102 are formed which extend over the top surface of the second level inter-layer insulator 104, so that the second level interconnections 102 are directly contact with the tops of the second level metal contact plugs 108. A third level inter-layer insulator 105 is further formed which extends over the top surface of the second level inter-layer insulator 104 so that the second level interconnections 102 are covered by the third level inter-layer insulator 105. Third level via holes are formed in the third level inter-layer insulator 105, so that the third level via holes are positioned over the second level interconnections 102. Third level metal contact plugs 109 are formed in the third level via holes, so that the bottoms of the third level metal contact plugs 109 are in contact directly with the tops of the second level interconnections 102. Subsequently, in order to stabilize characteristics of the transistors, a hydrogen anneal is carried out in a hydrogen-containing mixture gas atmosphere. Ferroelectric capacitors 110 are selectively formed over the top surface of the third inter-layer insulator 105, so that the bottoms of the ferroelectric capacitors 110 are in contact directly with the tops of the third level metal contact plugs 109, whereby the ferroelectric capacitors 110 are electrically connected through the third level metal contact plugs 109, the second level interconnections 102, the second level metal contact plugs 108, the first level interconnections 101 and the first level metal contact plugs 107 to the diffusion regions 106 of the transistors. Each of the ferroelectric capacitors 110 comprises laminations of a bottom electrode, a ferroelectric thin film and a top electrode. Subsequently, in order to improve characteristics of the ferroelectric capacitors 110, an oxygen anneal is carried out in an oxygen-containing atmosphere.

The ferroelectric capacitor is reduced in a residual dielectric polarization value by crystal defects and crystal damages just after the ferroelectric capacitor has been formed. In this state, no ideal hysteresis characteristics are obtained. The small residual dielectric polarization value means it difficult to distinguish binary digit levels, for example, 0 and 1.

In order to cause recovery to the crystal defects and crystal damages, a heat treatment is carried out in an oxygen-containing atmosphere at a temperature in the range of 400° C.-450° C. for 10 minutes to 30 minutes, thereby obtaining an ideal hysteresis characteristics of the ferroelectric capacitors.

The above described conventional semiconductor device and the conventional fabrication method have the following disadvantages. Accordingly, it is necessary that in order to cause recovery to the crystal defects and crystal damages, a heat treatment is carried out in an oxygen-containing atmosphere at a temperature in the range of 400° C.-450° C., after the ferroelectric capacitor has been formed. This heat treatment in the range of 400° C.-450° C. causes oxygen atoms to enter into the inter-layer insulator and reach the underlying metal interconnections, whereby the metal interconnections are oxidized, resulting in an increase in resistance of the metal interconnections. The increase in resistance of the metal interconnections drops the reliability of the semiconductor device.

In Japanese laid-open patent publication No. 11-317500, it is disclosed that after multi-level metal interconnections have been formed, the hydrogen anneal is carried out and then a thin film capacitor is formed before an oxygen anneal is carried out. In accordance with this conventional method, the metal interconnections underlying the thin film capacitors are oxidized by oxygen entered from the oxygen atmosphere in the oxygen anneal, thereby increasing the resistance of the oxidized metal interconnections.

In Japanese laid-open patent publication No. 9-246497, it is disclosed that a silicon nitride film is formed over CMOS transistors, and then ferroelectric capacitors are formed over the silicon nitride film, so that the CMOS transistors are protected by the silicon nitride film from subsequent oxygen anneal to the ferroelectric capacitors. However, metal interconnections are formed over the silicon nitride films and under the ferroelectric capacitors, for which reason the metal interconnections underling the thin film capacitors and overlying the silicon nitride film are oxidized by oxygen entered from the oxygen atmosphere in the oxygen anneal, thereby increasing the resistance of the oxidized metal interconnections.

In the above circumstances, it had been required to develop a novel semiconductor device and method of forming the same free from the above problem.

### SUMMARY OF THE INVENTION

Accordingly, it is an object of the present invention to provide a novel semiconductor device having capacitive elements and metal interconnections underling the capacitive elements free from the above problems.

It is a further object of the present invention to provide a novel semiconductor device having capacitive elements and metal interconnections underling the capacitive elements, wherein the metal interconnection is free from oxidation in an oxygen anneal to the capacitive elements.

It is a still further object of the present invention to provide a novel method of forming a semiconductor device having capacitive elements and metal interconnections underling the capacitive elements free from the above problems.

It is yet a further object of the present invention to provide a novel method of forming a semiconductor device having capacitive elements and metal interconnections underling the capacitive elements, wherein the metal interconnection is free from oxidation in an oxygen anneal to the capacitive elements.

The present invention provides a semiconductor device having at least a multilevel metal interconnection structure, at least a capacitor which lies over the multilevel metal interconnection structure, and an inter-layer insulator under the capacitor and over the multilevel metal interconnection structure for isolating the multilevel metal interconnection structure form the capacitor, wherein at least an anti-oxidizing film preventing penetration of oxygen is provided in the inter-layer insulator, so that the anti-oxidizing film lies covering the multilevel metal interconnection structure and under the capacitor.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a fragmentary cross sectional elevation view illustrative of a conventional semiconductor device having a capacitive element.

FIG. 2 is a fragmentary cross sectional elevation view illustrative of a first novel semiconductor device having capacitive elements and a multilevel interconnection structure underlying the capacitive elements in a first embodiment in accordance with the present invention.

FIGS. 3A through 3N are fragmentary cross sectional elevation views illustrative of first novel semiconductor devices in sequential steps involved in a first novel fabrication method in a first embodiment in accordance with the present invention.

FIG. 4 is a fragmentary cross sectional elevation view illustrative of a second novel semiconductor device having capacitive elements and a multilevel interconnection structure underlying the capacitive elements in a second embodiment in accordance with the present invention.

FIGS. 5A through 5K are fragmentary cross sectional elevation views illustrative of second novel semiconductor devices in sequential steps involved in a second novel fabrication method in a second embodiment in accordance with the present invention.

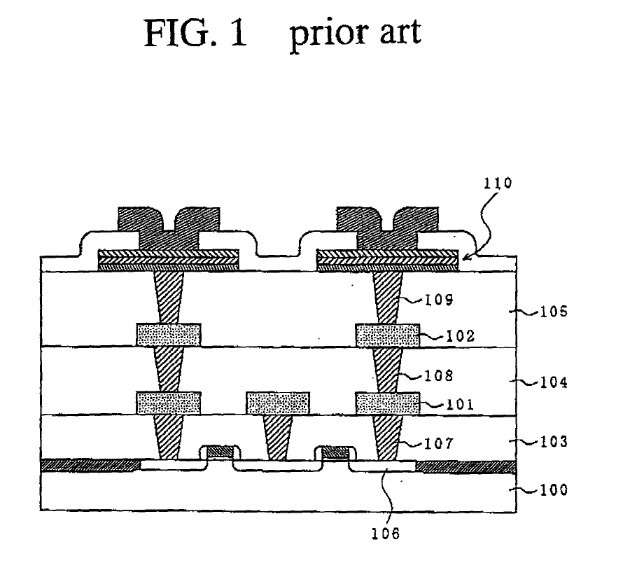

### DISCLOSURE OF THE INVENTION

The first present invention provides a semiconductor device having at least an electrically conductive structural element, at least a dielectric film which lies over the electrically conductive structural element, and an inter-layer insulator under the dielectric film and over the electrically conductive structural element for isolating the electrically conductive structural element form the dielectric film, wherein at least a film preventing penetration of oxygen is provided in the inter-layer insulator, so that the film lies covering the electrically conductive structural element and under the dielectric film.

Consequently, it is essential for the first present invention that the film capable of preventing penetration of oxygen lies covering or over the electrically conductive structural element such as the metal interconnection structure and under the dielectric film for allowing the film to protect the electrically conductive structural element from oxidation by oxygen from an oxygen-containing gas atmosphere during an oxygen heat treatment carried out in the oxygen-containing gas atmosphere to improve properties of the dielectric film.

It is preferable that the dielectric film comprises a ferroelectric film.

It is further preferable that the ferroelectric film is of a ferroelectric capacitor.

It is also preferable that the dielectric film comprises a high dielectric film having a high dielectric constant.

It is further preferable that the high dielectric film is of a high dielectric capacitor.

It is also preferable that the film comprises an anti-oxidizing film.

It is also preferable that the electrically conductive structural element comprises a multilevel metal interconnection structure, and the film lies over at least a top level interconnection of the multilevel metal interconnection structure.

It is also preferable that the electrically conductive structural element comprises a multilevel metal interconnection structure, and the film lies in contact with side walls and a top surface of at least a top level interconnection of the multilevel metal interconnection structure.

Namely, it is essential for the present invention that the film capable of preventing penetration of oxygen lies over the metal interconnection structure and under the bottom electrode of the capacitor having either the ferroelectric film or the high dielectric film for allowing the film to protect the metal interconnection structure from oxidation by oxygen from an oxygen-containing gas atmosphere during an oxygen heat treatment carried out in the oxygen-containing gas atmosphere to improve properties of either the ferroelectric film or the high dielectric film.

The second present invention provides a semiconductor device having at least a multilevel metal interconnection structure, at least a capacitor which lies over the multilevel metal interconnection structure, and an inter-layer insulator under the capacitor and over the multilevel metal interconnection structure for isolating the multilevel metal interconnection structure form the capacitor, wherein at least an anti-oxidizing film preventing penetration of oxygen is provided in the inter-layer insulator, so that the anti-oxidizing film lies covering the multilevel metal interconnection structure and under the capacitor. It is essential for the second present invention that the film capable of preventing penetration of oxygen lies over the metal interconnection structure and under the bottom electrode of the capacitor having either the ferroelectric film or the high dielectric film for allowing the film to protect the metal interconnection structure from oxidation by oxygen from an oxygen-containing gas atmosphere during an oxygen heat treatment carried out in the oxygen-containing gas atmosphere to improve properties of either the ferroelectric film or the high dielectric film.

It is preferable that the capacitor comprises a ferroelectric capacitor having a ferroelectric film.

It is also preferable that the capacitor has a high dielectric film having a high dielectric constant.

It is also preferable that the anti-oxidizing film lies over at least a top level interconnection of the multilevel metal interconnection structure.

It is also preferable that the anti-oxidizing film lies in contact with side walls and a top surface of at least a top level interconnection of the multilevel metal interconnection structure.

The third present invention provides a method of forming a semiconductor device comprising the steps of: forming at least an electrically conductive structural element; forming an inter-layer insulator over the electrically conductive structural element and the inter-layer insulator including at least a film preventing penetration of oxygen, and the film covering the electrically conductive structural element; and forming at least a dielectric film which lies over the inter-layer insulator; and carrying out a heat treatment in an oxygen-containing gas atmosphere. Consequently, it is essential for the third present invention that the film capable of preventing penetration of oxygen lies covering or over the electrically conductive structural element such as the metal interconnection structure and under the dielectric film for allowing the film to protect the electrically conductive structural element from oxidation by oxygen from an oxygen-containing gas atmosphere during an oxygen heat treatment carried out in the oxygen-containing gas atmosphere to improve properties of the dielectric film.

It is preferable that the dielectric film comprises a ferroelectric film.

It is further preferable that the ferroelectric film is of a ferroelectric capacitor.

It is also preferable that the dielectric film comprises a high dielectric film having a high dielectric constant.

It is further preferable that the high dielectric film is of a high dielectric capacitor.

It is also preferable that the film comprises an anti-oxidizing film.

It is also preferable that the electrically conductive structural element comprises a multilevel metal interconnection structure, and the film lies over at least a top level interconnection of the multilevel metal interconnection structure.

It is also preferable that the electrically conductive structural element comprises a multilevel metal interconnection structure, and the film lies in contact with side walls and a top surface of at least a top level interconnection of the multilevel metal interconnection structure.

The third present invention provides a method of forming a semiconductor device comprising the steps of: forming at least a multilevel metal interconnection structure; forming an inter-layer insulator over the multilevel metal interconnection structure, and the inter-layer insulator including at least an anti-oxidizing film preventing penetration of oxygen and the anti-oxidizing film covering the multilevel metal interconnection structure; forming at least a capacitor which lies over the multilevel metal interconnection structure; and carrying out a heat treatment in an oxygen-containing gas atmosphere. It is essential for the second present invention that the film capable of preventing penetration of oxygen lies over the metal interconnection structure and under the bottom electrode of the capacitor having either the ferroelectric film or the high dielectric film for allowing the film to protect the metal interconnection structure from oxidation by oxygen from an oxygen-containing gas atmosphere during an oxygen heat treatment carried out in the oxygen-containing gas atmosphere to improve properties of either the ferroelectric film or the high dielectric film.

It is preferable that the capacitor comprises a ferroelectric capacitor having a ferroelectric film.

It is also preferable that the capacitor has a high dielectric film having a high dielectric constant.

It is also preferable that the anti-oxidizing film lies over at least a top level interconnection of the multilevel metal interconnection structure.

It is also preferable that the anti-oxidizing film lies in contact with side walls and a top surface of at least a top level interconnection of the multilevel metal interconnection structure.

### PREFERRED EMBODIMENT

### First Embodiment

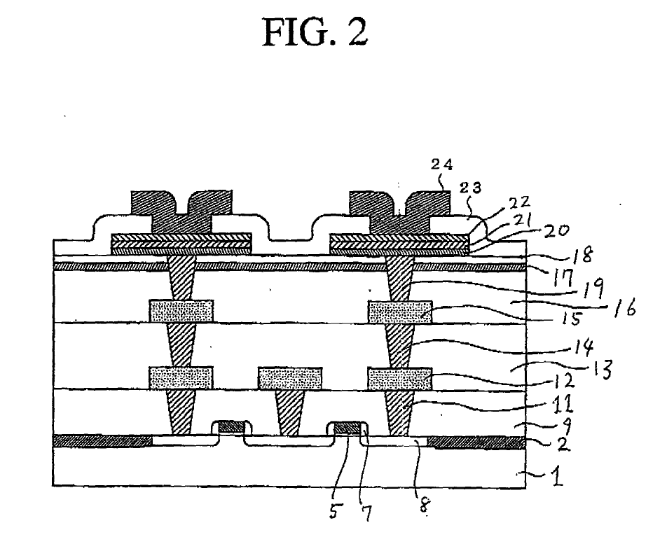

A first embodiment according to the present invention will be described in detail with reference to the drawings. FIG. 2 is a fragmentary cross sectional elevation view illustrative of a first novel semiconductor device having capacitive elements and a multilevel interconnection structure underlying the capacitive elements in a first embodiment in accordance with the present invention.

Field oxide films 2 are selectively provided on a surface of a silicon substrate 1. A gate oxide film 3 is provided on device formation regions of the silicon substrate 1. Gate electrodes 5 are provided on the gate oxide film 3. Side wall oxide films are provided on side walls of each of the gate electrodes 5. Diffusion regions 8 self-aligned to the gate electrodes and the side wall oxide films are provided in the device formation region of the substrate 1. A first level inter-layer insulator 9 is entirely provdied over the gate electrodes 5 and the side wall oxide films 7 as well as over the diffusion regions 8 and the field oxide films 2. The first level inter-layer insulator 9 may comprise a boro-phosphosilicate glass film which is deposited by a plasma enhanced chemical vapor deposition method. Via holes as first level via holes are formed in the first level inter-layer insulator 9, so that the via holes reach the diffusion regions 8. First level tungsten contact plugs 11 are provided in the via holes in the first level inter-layer insulator 9. First level interconnections 12 extend over the top surface of the first level inter-layer insulator 9, so that the first level interconnections 12 are in contact directly with the first level tungsten contact plugs 11, whereby the first level interconnections 12 are electrically connected through the first level tungsten contact plugs 11 to the diffusion regions 8. A second level inter-layer insulator 13 is entirely provided over the top surface of the first-level inter-layer insulator 13 and also over the first level interconnections 12, so that the first level interconnections 12 are completely buried within the second level inter-layer insulator 13. Second level via holes are formed in the second level inter-layer insulator 13, so that the second level via holes reach the top surfaces of the first level interconnections 12. Second level tungsten contact plugs 11 are provided in the via holes in the second level inter-layer insulator 9. Second level interconnections 15 extend over the top surface of the second level inter-layer insulator 13, so that the second level interconnections 15 are in contact directly with the second level tungsten contact plugs 14, whereby the second level interconnections 12 are electrically connected through the second level tungsten contact plugs 14, the first level interconnections 12 and the first level tungsten contact plugs 11 to the diffusion regions 8.

A third level inter-layer insulator 16 is entirely provided over the top surface of the second level inter-layer insulator 13 and the second level interconnections 15, whereby the second level interconnections 15 are completely buried with in the third level inter-layer insulator 16. An anti-oxidizing film 17 is entirely provided which extends over the top surface of the third level inter-layer insulator 16, whereby the second level interconnections 15 are completely covered by the anti-oxidizing film 17. The anti-oxidizing film 17 is capable of preventing oxygen from penetrating the anti-oxidizing film 17 and from reaching the second level interconnections 15. The anti-oxidizing film 17 may comprise a silicon nitride film (Si₃N₄) or a silicon oxy-nitride film (SiON). A thin inter-layer insulator 18 of silicon dioxide is further entirely provided on the top surface of the anti-oxidizing film 17. Third level via holes are formed which penetrate the thin inter-layer insulator 18, the anti-oxidizing film 17 and the third level inter-layer insulator 16 so that the third level via holes reach the top surfaces of the second level interconnections 15. Third level tungsten plugs 19 are formed in the third level via holes. A bottom electrode film 20, which comprises laminations of titanium and platinum films, is provided over the top surface of the thin inter-layer insulator 18 for a ferromagnetic capacitor. A ferroelectric film 21 of PZT(Pb(Ti, Zr)O₃) is provided on the top surface of the bottom electrode film 20. A top electrode film 22 comprising laminations of an iridium dioxide film (IrO₂) and an iridium film (Ir) is provided over the ferroelectric film 21. A top level inter-layer insulator 23 of ozone —TEOS (O₃TEOS) is provided, so that the top level inter-layer insulator 23 extends over the thin inter-layer insulator 18 and also over the ferroelectric capacitors, whereby the ferroelectric capacitors are completely buried with in the top level inter-layer insulator 23. Openings are formed in the top level inter-layer insulator 23 and positioned over the ferroelectric capacitors. Metal plate lines 24 are formed, wherein the metal plate lines 24 are in contact directly with the top electrode of the ferroelectric capacitors.

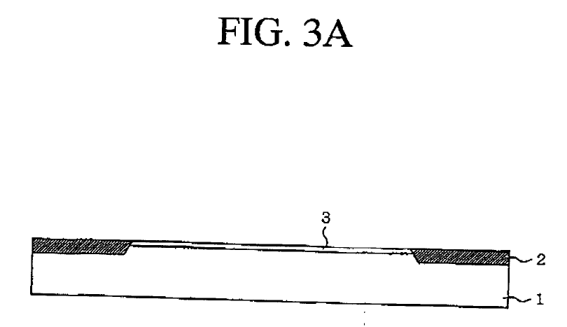

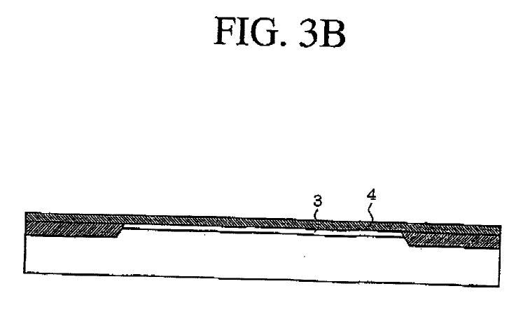

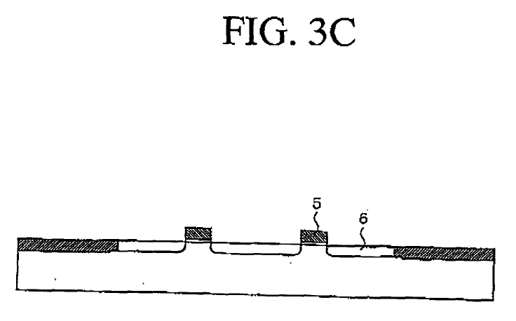

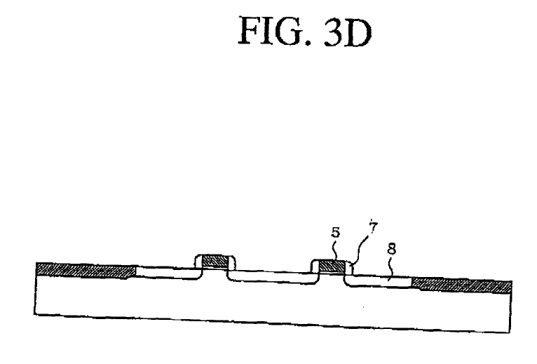

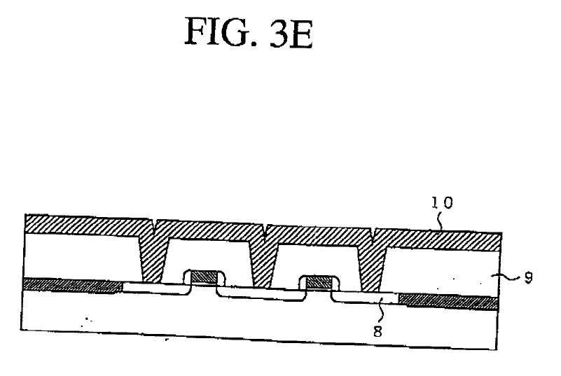

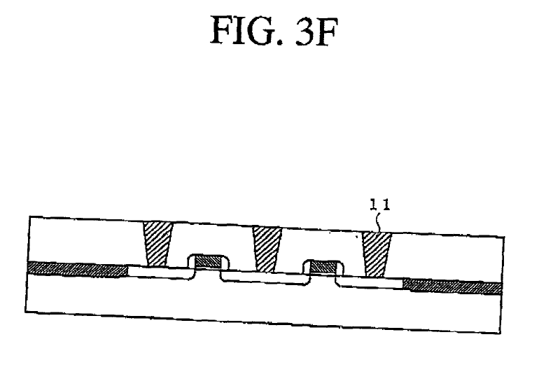

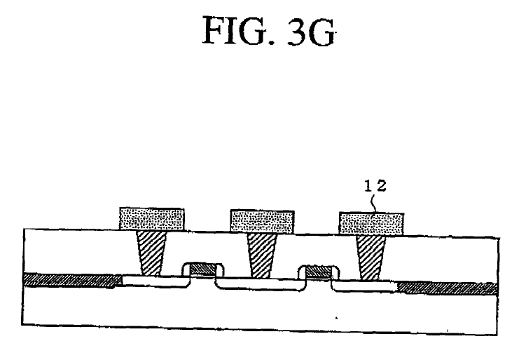

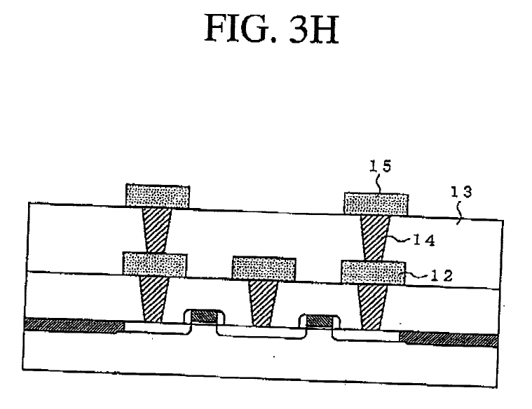

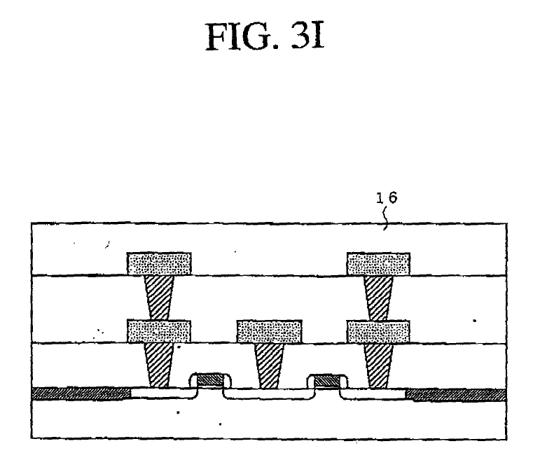

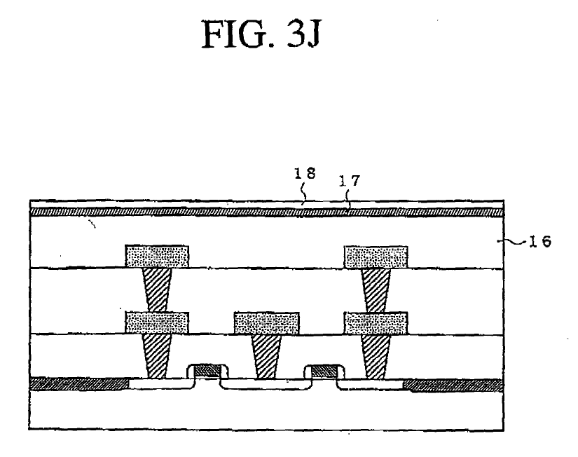

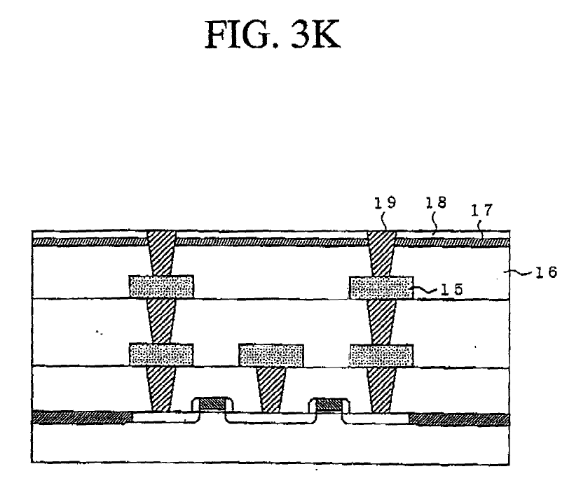

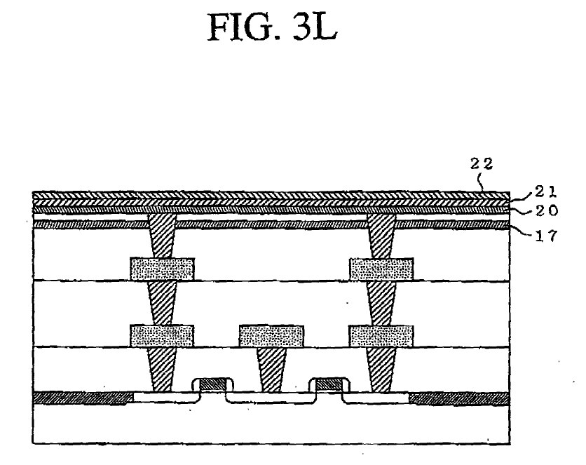

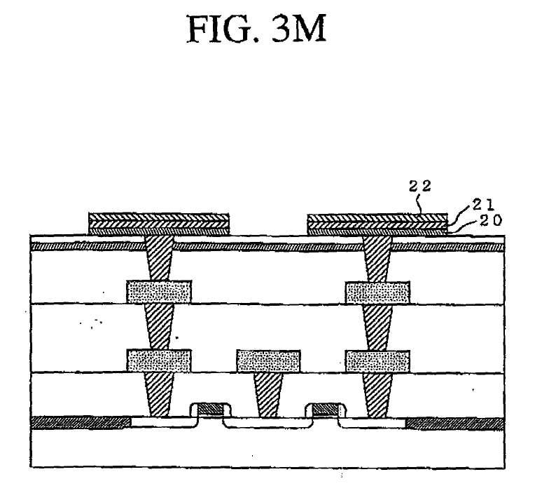

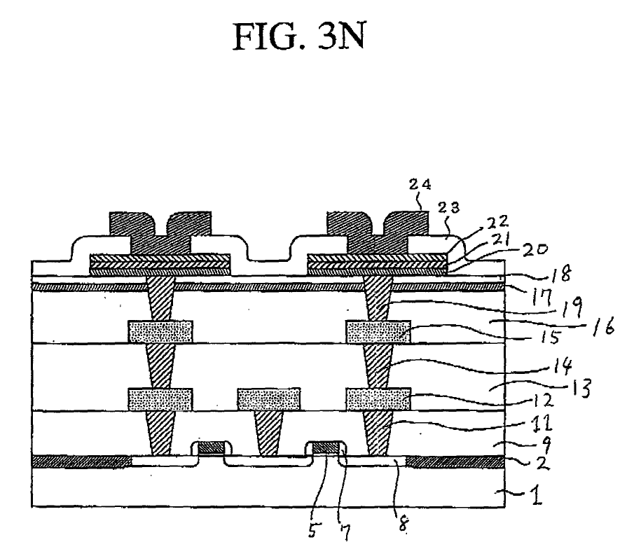

FIGS. 3A through 3N are fragmentary cross sectional elevation views illustrative of first novel semiconductor devices in sequential steps involved in a first novel fabrication method in a first embodiment in accordance with the present invention.

With reference to FIG. 3A, field oxide films 2 are selectively formed on a surface of a silicon substrate 1 by a local oxidation of silicon, thereby defining device formation regions defined by the field oxide films. A gate oxide film 3 is then formed over the device formation regions of the silicon substrate 1.

With reference to FIG. 3B, a gate lamination film 4 comprising laminations of a polycrystal silicon film and a tungsten silicide film is entirely deposited over the field oxide films 2 and the gate insulating film 3.

With reference to FIG. 3C, a photo-resist film is applied on the gate lamination film 4. The photo-resist film is then subjected to an exposure and subsequent development to form a photo-resist pattern. The photo-resist pattern is used as a mask to carry out a plasma etching as an anisotropic etching for selectively etching the gate lamination film 4 to form gate electrodes 5. An ion-implantation of phosphorus is carried out to introduce phosphorus into the device formation regions by use of the gate electrodes 5 as masks, whereby self-aligned diffusion regions 6 are then formed in the device formation region of the silicon substrate 1. The used photo-resist pattern is removed.

With reference to FIG. 3D, a chemical vapor deposition method is carried out to entirely deposit a silicon oxide film of high temperature oxide, so that the silicon oxide film covers the surfaces of the diffusion regions 6 and the field oxide films 2 and the gate electrodes 5. The silicon oxide film is then subjected to an isotropic etch-back, so that the silicon oxide films remain only on side walls of the gate electrodes 5, whereby side wall oxide films 7 are formed on the side walls of the gate electrodes. Subsequently, a further ion-implantation of arsenic is carried out to introduce arsenic into the diffusion regions 8 at a high impurity concentration by use of the gate electrodes 5 and the side wall oxide films 7 as masks to form lightly doped drain structures which are self-aligned to the side wall oxide films 7.

With reference to FIG. 3E, a first level inter-layer insulator 9 is entirely formed over the gate electrodes 5 and the side wall oxide films 7 as well as over the diffusion regions 8 and the field oxide films 2. The first level inter-layer insulator 9 may comprise a boro-phosphosilicate glass film which is deposited by a plasma enhanced chemical vapor deposition method. Via holes as first level via holes are formed in the first level inter-layer insulator 9, so that the via holes reach the diffusion regions 8. A tungsten film 10 is entirely deposited so that the tungsten film 10 completely fills the via holes and extend over the first level inter-layer insulator 9.

With reference to FIG. 3F, the tungsten film 10 is then subjected to an etch-back to remove the tungsten film 10 over the top surface of the first level inter-layer insulator 9 so that the tungsten film 10 remains only within the via holes, whereby first level tungsten contact plugs 11 are formed in the via holes in the first level inter-layer insulator 9.

With reference to FIG. 3G, a titanium film is entirely deposited by a sputtering method over the top surface of the first level inter-layer insulator 9 and over the tops of the first level tungsten contact plugs 11. A titanium nitride film is further entirely deposited on the titanium film by the sputtering method. An AlSiCu film is furthermore entirely deposited on the titanium nitride film. A titanium nitride film is moreover entirely deposited on the AlSiCu film, thereby forming a lamination structure comprising the titanium film, the titanium nitride film, AlSiCu film and the titanium nitride film over the top surface of the first level inter-layer insulator 9 and over the tops of the first level tungsten contact plugs 11. A photo-resist film is then applied on the titanium nitride film. The photo-resist film is then subjected to an exposure and subsequent development to form a photo-resist pattern over the lamination structure. An anisotropic etching is carried by use of the photo-resist pattern as a mask to pattern the lamination structure, whereby first level interconnections 12 which extend over the top surface of the first level inter-layer insulator 9, so that the first level interconnections 12 are in contact directly with the first level tungsten contact plugs 1, whereby the first level interconnections 12 are electrically connected through the first level tungsten contact plugs 11 to the diffusion regions 8.

With reference to FIG. 3H, a second level inter-layer insulator 13 is entirely formed over the top surface of the first-level inter-layer insulator 13 and also over the first level interconnections 12, so that the first level interconnections 12 are completely buried within the second level inter-layer insulator 13. Second level via holes are formed in the second level inter-layer insulator 13, so that the second level via holes reach the top surfaces of the first level interconnections 12. A tungsten film 14 is entirely deposited so that the tungsten film 14 completely fills the via holes and extend over the second level inter-layer insulator 13. The tungsten film 14 is then subjected to an etch-back to remove the tungsten film 14 over the top surface of the second level inter-layer insulator 13 so that the tungsten film 14 remains only within the via holes, whereby second level tungsten contact plugs 11 are formed in the via holes in the second level inter-layer insulator 9. A titanium film is entirely deposited by a sputtering method over the top surface of the second level inter-layer insulator 13 and over the tops of the second level tungsten contact plugs 14. A titanium nitride film is further entirely deposited on the titanium film by the sputtering method. An AlSiCu film is furthermore entirely deposited on the titanium nitride film. A titanium nitride film is moreover entirely deposited on the AlSiCu film, thereby forming a lamination structure comprising the titanium film, the titanium nitride film, AlSiCu film and the titanium nitride film over the top surface of the second level inter-layer insulator 13 and over the tops of the second level tungsten contact plugs 14. A photo-resist film is then applied on the titanium nitride film. The photo-resist film is then subjected to an exposure and subsequent development to form a photo-resist pattern over the lamination structure. An anisotropic etching is carried by use of the photo-resist pattern as a mask to pattern the lamination structure, whereby second level interconnections 15 which extend over the top surface of the second level inter-layer insulator 13, so that the second level interconnections 15 are in contact directly with the second level tungsten contact plugs 14, whereby the second level interconnections 12 are electrically connected through the second level tungsten contact plugs 14, the first level interconnections 12 and the first level tungsten contact plugs 11 to the diffusion regions 8.

With reference to FIG. 3I, a third level inter-layer insulator 16 is entirely deposited by a plasma enhanced chemical vapor deposition method over the top surface of the second level inter-layer insulator 13 and the second level interconnections 15, whereby the second level interconnections 15 are completely buried with in the third level inter-layer insulator 16. Subsequently, in order to stabilize the characteristics and performances of the transistors, a hydrogen anneal is carried out in a mixture gas atmosphere of hydrogen and nitrogen at a temperature of 400° C. for 5-30 minutes.

With reference to FIG. 3J, an anti-oxidizing film 17 is entirely formed which extends over the top surface of the third level inter-layer insulator 16, whereby the second level interconnections 15 are completely covered by the anti-oxidizing film 17. The anti-oxidizing film 17 is capable of preventing oxygen from penetrating the anti-oxidizing film 17 and from reaching the second level interconnections 15. The anti-oxidizing film 17 may comprise a silicon nitride film (Si₃N₄) or a silicon oxy-nitride film (SiON). The anti-oxidizing film 17 may be formed by a plasma enhanced chemical vapor deposit ion method or a sputtering method. A thin inter-layer insulator 18 of silicon dioxide is further entirely deposited on the top surface of the anti-oxidizing film 17 by a plasma enhanced chemical vapor deposition method.

With reference to FIG. 3K, third level via holes are formed which penetrate the thin inter-layer insulator 18, the anti-oxidizing film 17 and the third level inter-layer insulator 16 so that the third level via holes reach the top surfaces of the second level interconnections 15. A tungsten film is then entirely deposited by a chemical vapor deposition method, so that the tungsten film completely fills the third level via holes and extends over the top surface of the thin inter-layer insulator 18. The tungsten film is then subjected to an etch-back so that the tungsten film over the top surface of the thin inter-layer insulator 18 is removed and the tungsten film remains only within the third level via holes, whereby third level tungsten plugs 19 are formed in the third level via holes.

With reference to FIG. 3L, a titanium film is entirely deposited by a sputtering method over the top surface of the thin inter-layer insulator 18 and the tops of the third level tungsten plugs 19. A platinum film is entirely deposited by a sputtering method over the top surface of the titanium film, whereby a bottom electrode film 20, which comprises laminations of the titanium and platinum films, is formed over the top surface of the thin inter-layer insulator 18 for a ferromagnetic capacitor. A ferroelectric film 21 of PZT(Pb(Ti, Zr)O₃) is formed on the top surface of the bottom electrode film 20 by a metal organic chemical vapor deposition method. Subsequently, in order to improve properties of the ferroelectric film 21, an oxygen anneal is carried out in an oxygen-containing gas atmosphere at a temperature in the range of 400° C. to 450° C. for 30 minutes. Oxygen is prevented from penetrating the anti-oxidizing film 17 so that no oxygen reach the second level interconnections 15. No oxidation appears on the second level interconnections 15. Namely, the second level interconnections 15 are protected from oxidation by the anti-oxidizing film 17 during the oxygen anneal for improving the properties of the ferroelectric film 21. Subsequently, an iridium dioxide film (IrO₂) is deposited on the top surface of the ferroelectric film 21 by the sputtering method. Further, an iridium film (Ir) is deposited on the top surface of the iridium dioxide film (IrO₂) by the sputtering method, whereby a top electrode film 22 comprising the laminations of the iridium dioxide film (IrO₂) and the iridium film (Ir) is accordingly formed over the ferroelectric film 21.

With reference to FIG. 3M, a photo-resist film is applied on the top electrode film 22. The photo-resist film is then subjected to an exposure and subsequent development to form a photo-resist pattern over the top electrode film 22. The photo-resist pattern is used as a mask to carry out an anisotropic etching for patterning the lamination structure of the bottom electrode film 20, the ferroelectric film 21 and the top electrode film 22, whereby ferroelectric capacitors are formed over the thin inter-layer insulator 18. As a result, the bottom electrode 20 of the ferroelectric capacitor is electrically connected through the third level contact plug 19, the second level interconnection 15, the second level contact plug 14, the first level interconnection 12, and the first level contact plug 11 to the diffusion region 8 of the transistor. It is possible that the top electrode film 22, the ferroelectric film 21 and the bottom electrode film 20 are then patterned by a batch anisotropic etching process. It is, alternatively, possible that the top electrode film 22 is patterned by a first time anisotropic etching process, before the ferroelectric film 21 and the bottom electrode film 20 are then patterned by a second time anisotropic etching process. Subsequently, a heat treatment is then carried out in an oxygen-containing atmosphere at a temperature in the range of 400° C.-450° C. for 30 minutes.

With reference to FIG. 3N, a top level inter-layer insulator 23 of ozone —TEOS (O₃TEOS) is entirely deposited by a chemical vapor deposition method, so that the top level inter-layer insulator 23 extends over the thin inter-layer insulator 18 and also over the ferroelectric capacitors, whereby the ferroelectric capacitors are completely buried with in the top level inter-layer insulator 23. Openings are formed in the top level inter-layer insulator 23 and positioned over the ferroelectric capacitors, so that parts of the top surfaces of the top electrodes 22 of the ferroelectric capacitors are then shown through the openings in the top inter-layer insulator 23. An iridium dioxide film (IrO₂) is entirely deposited on the top surface of the top inter-layer insulator 23 and on the side walls of the openings and on the shown top parts of the top electrodes 22 of the ferroelectric capacitors by the sputtering method. Further, an iridium film (Ir) is deposited on the top surface of the iridium dioxide film (IrO₂) by the sputtering method, whereby a metal interconnection layer comprising laminations of the iridium dioxide film (IrO₂) and the iridium film (Ir) are accordingly formed on the top surface of the top inter-layer insulator 23 and on the side walls of the openings and on the shown top parts of the top electrodes 22 of the ferroelectric capacitors. A photo-resist film is then applied on the metal interconnection layer comprising laminations of the iridium dioxide film (IrO₂) and the iridium film (Ir). The photo-resist film is then subjected to an exposure and subsequent development to form a photo-resist pattern over the top inter-layer insulator 23. The photo-resist film is then used as a mask to carry out an anisotropic etching process for patterning the metal interconnection layer comprising laminations of the iridium dioxide film (IrO₂) and the iridium film (Ir), whereby metal plate lines 24 are formed, wherein the metal plate lines 24 are in contact directly with the top electrode of the ferroelectric capacitors. Each of the metal plate lines 24 may alternatively comprise laminations of a titanium nitride film and an aluminum film. Each of the metal plate lines 24 may further alternatively comprise an aluminum film or a copper film. Subsequently, a heat treatment is carried out in a nitrogen atmosphere at a temperature in the range of 400° C. to 450° C. for 30 minutes. Further, non-illustrated silicon nitride film as a cover film is then entirely formed by a plasma enhanced chemical vapor deposition method.

In accordance with the present invention, it is important that the anti-oxidizing film may be formed over the top level metal interconnections and under the bottom electrode of the ferroelectric capacitor for allowing the anti-oxidizing film to protect the top level metal interconnections from oxidation by oxygen from an oxygen-containing gas atmosphere during an oxygen heat treatment carried out in the oxygen-containing gas atmosphere.

It is, for example, possible that the anti-oxidizing film is formed over the top inter-layer insulator over the multilevel interconnection structure, and the bottom electrode of the ferroelectric capacitor is formed on the top surface of the anti-oxidizing film.

Accordingly, it is essential for the present invention that the film capable of preventing penetration of oxygen lies over the metal interconnection structure such as the multilevel interconnection structure and under the bottom electrode of the ferroelectric capacitor for allowing the anti-oxidizing film to protect the top level metal interconnections from oxidation by oxygen from an oxygen-containing gas atmosphere during an oxygen heat treatment carried out in the oxygen-containing gas atmosphere.

In accordance with the above embodiment, the multilevel interconnection structure has two levels. Notwithstanding, three or more level interconnection structure may also be protected by the anti-oxidizing film which lies over the interconnection structure and under the bottom electrode of the ferroelectric capacitor. Further, a single level interconnection structure may also be protected by the anti-oxidizing film which lies over the single level interconnection structure and under the bottom electrode of the ferroelectric capacitor.

In accordance with the above embodiment, the semiconductor device, to which the present invention is applied, is the semiconductor device having the ferroelectric capacitors. Notwithstanding, the present invention may also be applied to a semiconductor device having a dielectric capacitor having a high dielectric with a high dielectric constant. The dynamic random access memory device is one of the semiconductor devices, to which the present invention may be applied.

Consequently, it is essential for the present invention that the film capable of preventing penetration of oxygen lies over the metal interconnection structure and under the bottom electrode of the capacitor having either the ferroelectric film or the high dielectric film for allowing the film to protect the metal interconnection structure from oxidation by oxygen from an oxygen-containing gas atmosphere during an oxygen heat treatment carried out in the oxygen-containing gas atmosphere to improve properties of either the ferroelectric film or the high dielectric film.

### Second Embodiment

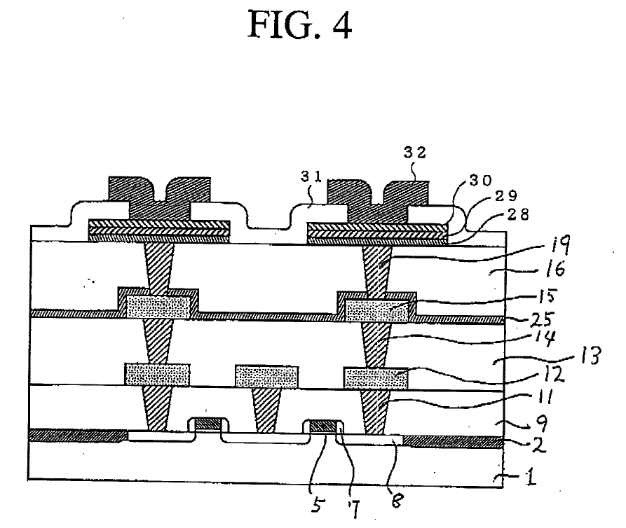

A second embodiment according to the present invention will be described in detail with reference to the drawings. FIG. 4 is a fragmentary cross sectional elevation view illustrative of a second novel semiconductor device having capacitive elements and a multilevel interconnection structure underlying the capacitive elements in a second embodiment in accordance with the present invention.

Field oxide films 2 are selectively provided on a surface of a silicon substrate 1. A gate oxide film 3 is provided on device formation regions of the silicon substrate 1. Gate electrodes 5 are provided on the gate oxide film 3. Side wall oxide films are provided on side walls of each of the gate electrodes 5. Diffusion regions 8 self-aligned to the gate electrodes and the side wall oxide films are provided in the device formation region of the substrate 1. A first level inter-layer insulator 9 is entirely provdied over the gate electrodes 5 and the side wall oxide films 7 as well as over the diffusion regions 8 and the field oxide films 2. The first level inter-layer insulator 9 may comprise a boro-phosphosilicate glass film which is deposited by a plasma enhanced chemical vapor deposition method. Via holes as first level via holes are formed in the first level inter-layer insulator 9, so that the via holes reach the diffusion regions 8. First level tungsten contact plugs 11 are provided in the via holes in the first level inter-layer insulator 9. First level interconnections 12 extend over the top surface of the first level inter-layer insulator 9, so that the first level interconnections 12 are in contact directly with the first level tungsten contact plugs 11, whereby the first level interconnections 12 are electrically connected through the first level tungsten contact plugs 11 to the diffusion regions 8. A second level inter-layer insulator 13 is entirely provided over the top surface of the first-level inter-layer insulator 13 and also over the first level interconnections 12, so that the first level interconnections 12 are completely buried within the second level inter-layer insulator 13. Second level via holes are formed in the second level inter-layer insulator 13, so that the second level via holes reach the top surfaces of the first level interconnections 12. Second level tungsten contact plugs 11 are provided in the via holes in the second level inter-layer insulator 9. Second level interconnections 15 extend over the top surface of the second level inter-layer insulator 13, so that the second level interconnections 15 are in contact directly with the second level tungsten contact plugs 14, whereby the second level interconnections 12 are electrically connected through the second level tungsten contact plugs 14, the first level interconnections 12 and the first level tungsten contact plugs 11 to the diffusion regions 8.

An anti-oxidizing film 25 is entirely provided which extends over the top surface of the second level inter-layer insulator 13 and the second level interconnections 15, whereby the second level interconnections 15 are completely covered with in the third level inter-layer insulator 16. The anti-oxidizing film 25 is capable of preventing oxygen from penetrating the anti-oxidizing film 25 and from reaching the second level interconnections 15. The anti-oxidizing film 25 may comprise a silicon nitride film (Si₃N₄) or a silicon oxy-nitride film (SiON). The anti-oxidizing film 25 may be formed by a plasma enhanced chemical vapor deposition method or a sputtering method. A third level inter-layer insulator 26 is entirely provided over the anti-oxidizing film 25. Third level via holes are formed which penetrate the third level inter-layer insulator 26 and the anti-oxidizing film 25 so that the third level via holes reach the top surfaces of the second level interconnections 15. Third level tungsten plugs 27 are provided in the third level via holes. A bottom electrode film 28, which comprises laminations of titanium and platinum films, is provided over the top surface of the third level inter-layer insulator 26 for a ferromagnetic capacitor. A ferroelectric film 29 of PZT(Pb(Ti, Zr)O₃) is provided on the top surface of the bottom electrode film 28. A top electrode film 30 comprising laminations of an iridium dioxide film (IrO₂) and an iridium film (Ir) is provided over the ferroelectric film 29. A top level inter-layer insulator 31 of ozone —TEOS (O₃TEOS) is entirely provided, so that the top level inter-layer insulator 31 extends over the third level inter-layer insulator 16 and also over the ferroelectric capacitors, whereby the ferroelectric capacitors are completely buried with in the top level inter-layer insulator 31. Openings are formed in the top level inter-layer insulator 31 and positioned over the ferroelectric capacitors, so that parts of the top surfaces of the top electrodes 30 of the ferroelectric capacitors are then shown through the openings in the top inter-layer insulator 31. Metal plate lines 32 are provided, wherein the metal plate lines 32 are in contact directly with the top electrode of the ferroelectric capacitors. Each of the metal plate lines 32 may alternatively comprise laminations of a titanium nitride film and an aluminum film. Each of the metal plate lines 32 may further alternatively comprise an aluminum film or a copper film.

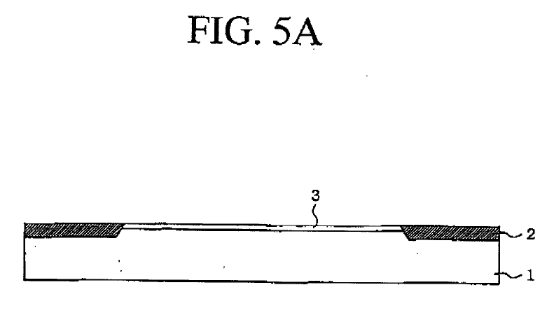

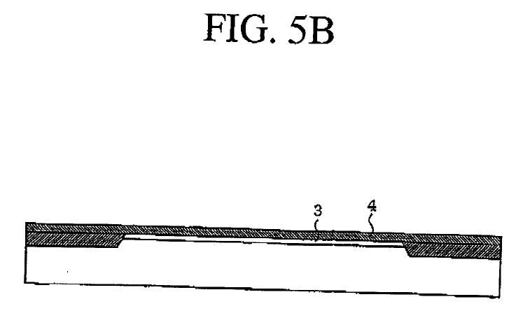

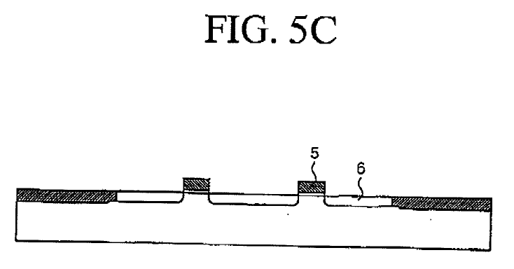

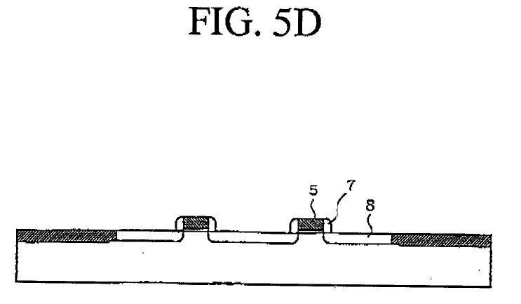

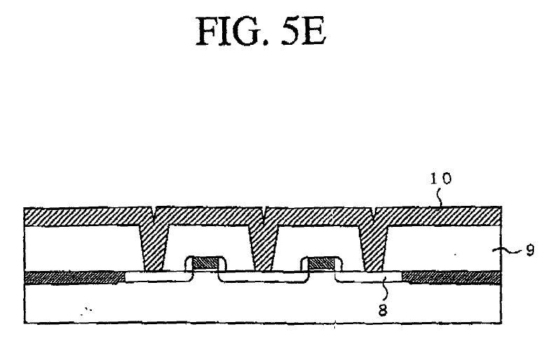

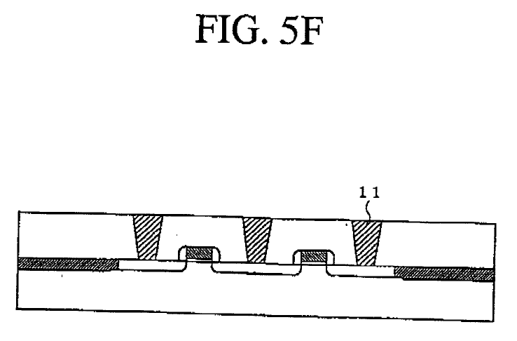

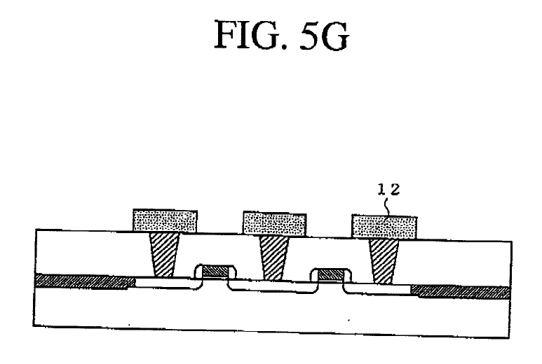

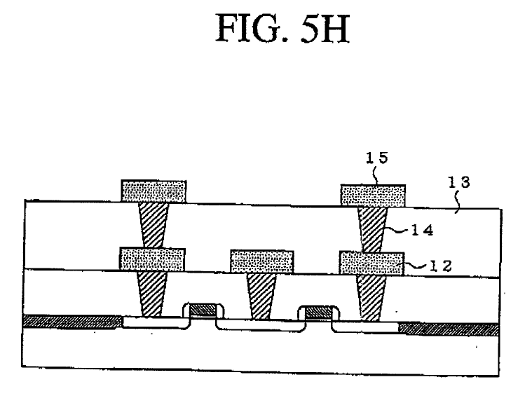

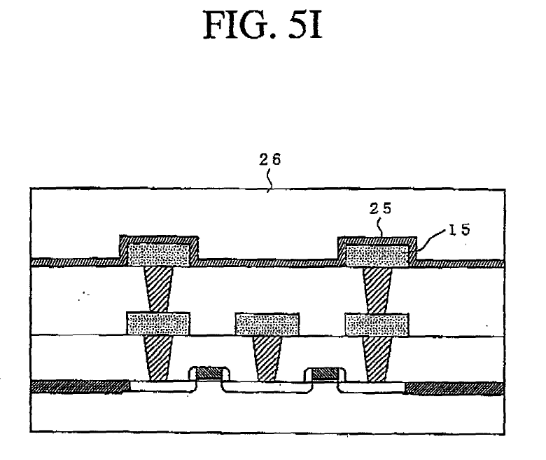

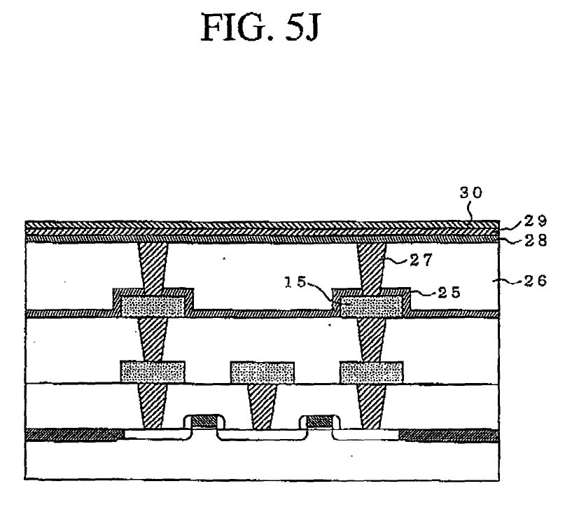

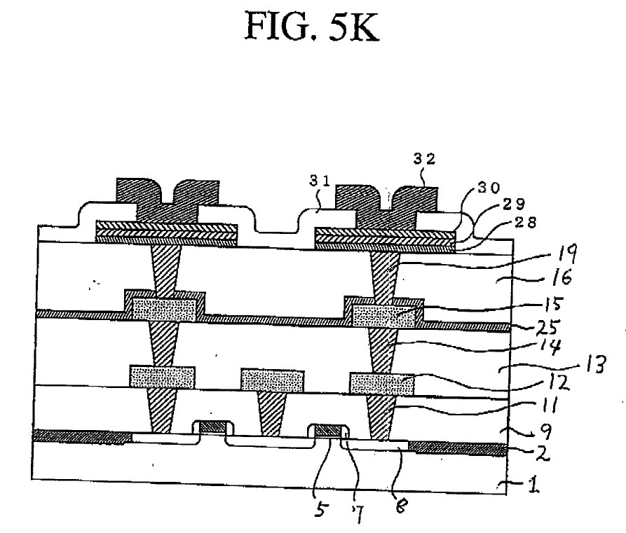

FIGS. 5A through 5K are fragmentary cross sectional elevation views illustrative of second novel semiconductor devices in sequential steps involved in a second novel fabrication method in a second embodiment in accordance with the present invention.

With reference to FIG. 5A, field oxide films 2 are selectively formed on a surface of a silicon substrate 1 by a local oxidation of silicon, thereby defining device formation regions defined by the field oxide films. A gate oxide film 3 is then formed over the device formation regions of the silicon substrate 1.

With reference to FIG. 5B, a gate lamination film 4 comprising laminations of a polycrystal silicon film and a tungsten silicide film is entirely deposited over the field oxide films 2 and the gate insulating film 3.

With reference to FIG. 5C, a photo-resist film is applied on the gate lamination film 4. The photo-resist film is then subjected to an exposure and subsequent development to form a photo-resist pattern. The photo-resist pattern is used as a mask to carry out a plasma etching as an anisotropic etching for selectively etching the gate lamination film 4 to form gate electrodes 5. An ion-implantation of phosphorus is carried out to introduce phosphorus into the device formation regions by use of the gate electrodes 5 as masks, whereby self-aligned diffusion regions 6 are then formed in the device formation region of the silicon substrate 1. The used photo-resist pattern is removed.

With reference to FIG. 5D, a chemical vapor deposition method is carried out to entirely deposit a silicon oxide film of high temperature oxide, so that the silicon oxide film covers the surfaces of the diffusion regions 6 and the field oxide films 2 and the gate electrodes 5. The silicon oxide film is then subjected to an isotropic etch-back, so that the silicon oxide films remain only on side walls of the gate electrodes 5, whereby side wall oxide films 7 are formed on the side walls of the gate electrodes. Subsequently, a further ion-implantation of arsenic is carried out to introduce arsenic into the diffusion regions 8 at a high impurity concentration by use of the gate electrodes 5 and the side wall oxide films 7 as masks to form lightly doped drain structures which are self-aligned to the side wall oxide films 7.

With reference to FIG. 5E, a first level inter-layer insulator 9 is entirely formed over the gate electrodes 5 and the side wall oxide films 7 as well as over the diffusion regions 8 and the field oxide films 2. The first level inter-layer insulator 9 may comprise a boro-phosphosilicate glass film which is deposited by a plasma enhanced chemical vapor deposition method. Via holes as first level via holes are formed in the first level inter-layer insulator 9, so that the via holes reach the diffusion regions 8. A tungsten film 10 is entirely deposited so that the tungsten film 10 completely fills the via holes and extend over the first level inter-layer insulator 9.

With reference to FIG. 5F, the tungsten film 10 is then subjected to an etch-back to remove the tungsten film 10 over the top surface of the first level inter-layer insulator 9 so that the tungsten film 10 remains only within the via holes, whereby first level tungsten contact plugs 11 are formed in the via holes in the first level inter-layer insulator 9.

With reference to FIG. 5G, a titanium film is entirely deposited by a sputtering method over the top surface of the first level inter-layer insulator 9 and over the tops of the first level tungsten contact plugs 11. A titanium nitride film is further entirely deposited on the titanium film by the sputtering method. An AlSiCu film is furthermore entirely deposited on the titanium nitride film. A titanium nitride film is moreover entirely deposited on the AlSiCu film, thereby forming a lamination structure comprising the titanium film, the titanium nitride film, AlSiCu film and the titanium nitride film over the top surface of the first level inter-layer insulator 9 and over the tops of the first level tungsten contact plugs 11. A photo-resist film is then applied on the titanium nitride film. The photo-resist film is then subjected to an exposure and subsequent development to form a photo-resist pattern over the lamination structure. An anisotropic etching is carried by use of the photo-resist pattern as a mask to pattern the lamination structure, whereby first level interconnections 12 which extend over the top surface of the first level inter-layer insulator 9, so that the first level interconnections 12 are in contact directly with the first level tungsten contact plugs 11, whereby the first level interconnections 12 are electrically connected through the first level tungsten contact plugs 11 to the diffusion regions 8.

With reference to FIG. 5H, a second level inter-layer insulator 13 is entirely formed over the top surface of the first-level inter-layer insulator 13 and also over the first level interconnections 12, so that the first level interconnections 12 are completely buried within the second level inter-layer insulator 13. Second level via holes are formed in the second level inter-layer insulator 13, so that the second level via holes reach the top surfaces of the first level interconnections 12. A tungsten film 14 is entirely deposited so that the tungsten film 14 completely fills the via holes and extend over the second level inter-layer insulator 13. The tungsten film 14 is then subjected to an etch-back to remove the tungsten film 14 over the top surface of the second level inter-layer insulator 13 so that the tungsten film 14 remains only within the via holes, whereby second level tungsten contact plugs 11 are formed in the via holes in the second level inter-layer insulator 9. A titanium film is entirely deposited by a sputtering method over the top surface of the second level inter-layer insulator 13 and over the tops of the second level tungsten contact plugs 14. A titanium nitride film is further entirely deposited on the titanium film by the sputtering method. An AlSiCu film is furthermore entirely deposited on the titanium nitride film. A titanium nitride film is moreover entirely deposited on the AlSiCu film, thereby forming a lamination structure comprising the titanium film, the titanium nitride film, AlSiCu film and the titanium nitride film over the top surface of the second level inter-layer insulator 13 and over the tops of the second level tungsten contact plugs 14. A photo-resist film is then applied on the titanium nitride film. The photo-resist film is then subjected to an exposure and subsequent development to form a photo-resist pattern over the lamination structure. An anisotropic etching is carried by use of the photo-resist pattern as a mask to pattern the lamination structure, whereby second level interconnections 15 which extend over the top surface of the second level inter-layer insulator 13, so that the second level interconnections 15 are in contact directly with the second level tungsten contact plugs 14, whereby the second level interconnections 12 are electrically connected through the second level tungsten contact plugs 14, the first level interconnections 12 and the first level tungsten contact plugs 11 to the diffusion regions 8.

With reference to FIG. 5I, an anti-oxidizing film 25 is entirely formed which extends over the top surface of the second level inter-layer insulator 13 and the second level interconnections 15, whereby the second level interconnections 15 are completely covered with in the third level inter-layer insulator 16. The anti-oxidizing film 25 is capable of preventing oxygen from penetrating the anti-oxidizing film 25 and from reaching the second level interconnections 15. The anti-oxidizing film 25 may comprise a silicon nitride film (Si₃N₄) or a silicon oxy-nitride film (SiON). The anti-oxidizing film 25 may be formed by a plasma enhanced chemical vapor deposition method or a sputtering method. Subsequently, a third level inter-layer insulator 26 is entirely deposited by a plasma enhanced chemical vapor deposition method over the anti-oxidizing film 25.

With reference to FIG. 5J, third level via holes are formed which penetrate the third level inter-layer insulator 26 and the anti-oxidizing film 25 so that the third level via holes reach the top surfaces of the second level interconnections 15. A tungsten film is then entirely deposited by a chemical vapor deposition method, so that the tungsten film completely fills the third level via holes and extends over the top surface of the third level inter-layer insulator 26. The tungsten film is then subjected to an etch-back so that the tungsten film over the top surface of the third level inter-layer insulator 26 is removed and the tungsten film remains only within the third level via holes, whereby third level tungsten plugs 27 are formed in the third level via holes. A titanium film is entirely deposited by a sputtering method over the third level inter-layer insulator 26 and the tops of the third level tungsten plugs 27. A platinum film is entirely deposited by a sputtering method over the top surface of the titanium film, whereby a bottom electrode film 28, which comprises laminations of the titanium and platinum films, is formed over the top surface of the third level inter-layer insulator 26 for a ferromagnetic capacitor. A ferroelectric film 29 of PZT(Pb(Ti, Zr)O₃) is formed on the top surface of the bottom electrode film 28 by a metal organic chemical vapor deposition method. Subsequently, in order to improve properties of the ferroelectric film 29, an oxygen anneal is carried out in an oxygen-containing gas atmosphere at a temperature in the range of 400° C. to 450° C. for 30 minutes. Oxygen is prevented from penetrating the anti-oxidizing film 25 so that no oxygen reach the second level interconnections 15. No oxidation appears on the second level interconnections 15. Namely, the second level interconnections 15 are protected from oxidation by the anti-oxidizing film 25 during the oxygen anneal for improving the properties of the ferroelectric film 29. Subsequently, an iridium dioxide film (IrO₂) is deposited on the top surface of the ferroelectric film 29 by the sputtering method. Further, an iridium film (Ir) is deposited on the top surface of the iridium dioxide film (IrO₂) by the sputtering method, whereby a top electrode film 30 comprising the laminations of the iridium dioxide film (IrO₂) and the iridium film (Ir) is accordingly formed over the ferroelectric film 29.

With reference to FIG. 5K, a photo-resist film is applied on the top electrode film 30. The photo-resist film is then subjected to an exposure and subsequent development to form a photo-resist pattern over the top electrode film 30. The photo-resist pattern is used as a mask to carry out an anisotropic etching for patterning the lamination structure of the bottom electrode film 28, the ferroelectric film 29 and the top electrode film 30, whereby ferroelectric capacitors are formed over the third level inter-layer insulator 16. As a result, the bottom electrode 28 of the ferroelectric capacitor is electrically connected through the third level contact plug 19, the second level interconnection 15, the second level contact plug 14, the first level interconnection 12, and the first level contact plug 11 to the diffusion region 8 of the transistor. It is possible that the top electrode film 30, the ferroelectric film 29 and the bottom electrode film 28 are then patterned by a batch anisotropic etching process. It is, alternatively, possible that the top electrode film 30 is patterned by a first time anisotropic etching process, before the ferroelectric film 29 and the bottom electrode film 28 are then patterned by a second time anisotropic etching process. Subsequently, a heat treatment is then carried out in an oxygen-containing atmosphere at a temperature in the range of 400° C.-450° C. for 30 minutes. A top level inter-layer insulator 31 of ozone —TEOS (O₃TEOS) is entirely deposited by a chemical vapor deposition method, so that the top level inter-layer insulator 31 extends over the third level inter-layer insulator 16 and also over the ferroelectric capacitors, whereby the ferroelectric capacitors are completely buried with in the top level inter-layer insulator 31. Openings are formed in the top level inter-layer insulator 31 and positioned over the ferroelectric capacitors, so that parts of the top surfaces of the top electrodes 30 of the ferroelectric capacitors are then shown through the openings in the top inter-layer insulator 31. An iridium dioxide film (IrO₂) is entirely deposited on the top surface of the top inter-layer insulator 31 and on the side walls of the openings and on the shown top parts of the top electrodes 30 of the ferroelectric capacitors by the sputtering method. Further, an iridium film (Ir) is deposited on the top surface of the iridium dioxide film (IrO₂) by the sputtering method, whereby a metal interconnection layer comprising laminations of the iridium dioxide film (IrO₂) and the iridium film (Ir) are accordingly formed on the top surface of the top inter-layer insulator 31 and on the side walls of the openings and on the shown top parts of the top electrodes 30 of the ferroelectric capacitors. A photo-resist film is then applied on the metal interconnection layer comprising laminations of the iridium dioxide film (IrO₂) and the iridium film (Ir). The photo-resist film is then subjected to an exposure and subsequent development to form a photo-resist pattern over the top inter-layer insulator 31. The photo-resist film is then used as a mask to carry out an anisotropic etching process for patterning the metal interconnection layer comprising laminations of the iridium dioxide film (IrO₂) and the iridium film (Ir), whereby metal plate lines 32 are formed, wherein the metal plate lines 32 are in contact directly with the top electrode of the ferroelectric capacitors. Each of the metal plate lines 32 may alternatively comprise laminations of a titanium nitride film and an aluminum film. Each of the metal plate lines 32 may further alternatively comprise an aluminum film or a copper film. Subsequently, a heat treatment is carried out in a nitrogen atmosphere at a temperature in the range of 400° C. to 450° C. for 30 minutes. Further, non-illustrated silicon nitride film as a cover film is then entirely formed by a plasma enhanced chemical vapor deposition method.

In accordance with the present invention, it is important that the anti-oxidizing film may be formed over the top level metal interconnections and under the bottom electrode of the ferroelectric capacitor for allowing the anti-oxidizing film to protect the top level metal interconnections from oxidation by oxygen from an oxygen-containing gas atmosphere during an oxygen heat treatment carried out in the oxygen-containing gas atmosphere.

It is, for example, possible that the anti-oxidizing film is formed over the top inter-layer insulator over the multilevel interconnection structure, and the bottom electrode of the ferroelectric capacitor is formed on the top surface of the anti-oxidizing film.

Accordingly, it is essential for the present invention that the film capable of preventing penetration of oxygen lies over the metal interconnection structure such as the multilevel interconnection structure and under the bottom electrode of the ferroelectric capacitor for allowing the anti-oxidizing film to protect the top level metal interconnections from oxidation by oxygen from an oxygen-containing gas atmosphere during an oxygen heat treatment carried out in the oxygen-containing gas atmosphere.

In accordance with the above embodiment, the multilevel interconnection structure has two levels. Notwithstanding, three or more level interconnection structure may also be protected by the anti-oxidizing film which lies over the interconnection structure and under the bottom electrode of the ferroelectric capacitor. Further, a single level interconnection structure may also be protected by the anti-oxidizing film which lies over the single level interconnection structure and under the bottom electrode of the ferroelectric capacitor.

In accordance with the above embodiment, the semiconductor device, to which the present invention is applied, is the semiconductor device having the ferroelectric capacitors. Notwithstanding, the present invention may also be applied to a semiconductor device having a dielectric capacitor having a high dielectric with a high dielectric constant. The dynamic random access memory device is one of the semiconductor devices, to which the present invention may be applied.

Consequently, it is essential for the present invention that the film capable of preventing penetration of oxygen lies over the metal interconnection structure and under the bottom electrode of the capacitor having either the ferroelectric film or the high dielectric film for allowing the film to protect the metal interconnection structure from oxidation by oxygen from an oxygen-containing gas atmosphere during an oxygen heat treatment carried out in the oxygen-containing gas atmosphere to improve properties of either the ferroelectric film or the high dielectric film.

Whereas modifications of the present invention will be apparent to a person having ordinary skill in the art, to which the invention pertains, it is to be understood that embodiments as shown and described by way of illustrations are by no means intended to be considered in a limiting sense. Accordingly, it is to be intended to cover by claims all modifications which fall within the spirit and scope of the present invention.

What is claimed is:

1. A semiconductor device having at least an electrically conductive structural element, at least a dielectric film which lies over said electrically conductive structural element, and an inter-layer insulator under said dielectric film and over said electrically conductive structural element for isolating said electrically conductive structural element form said dielectric film,
wherein at least a film preventing penetration of oxygen is provided in said inter-layer insulator, so that said film lies covering the electrically conductive structural element and under the dielectric film.

2. The semiconductor device as claimed in claim 1, wherein the dielectric film comprises a ferroelectric film.

3. The semiconductor device as claimed in claim 2, wherein the ferroelectric film is of a ferroelectric capacitor.

4. The semiconductor device as claimed in claim 1, wherein the dielectric film comprises a high dielectric film having a high dielectric constant.

5. The semiconductor device as claimed in claim 4, wherein the high dielectric film is of a high dielectric capacitor.

6. The semiconductor device as claimed in claim 1, wherein said film comprises an anti-oxidizing film.

7. The semiconductor device as claimed in claim 1, wherein said electrically conductive structural element comprises a multilevel metal interconnection structure, and said film lies over at least a top level interconnection of said multilevel metal interconnection structure.

8. The semiconductor device as claimed in claim 1, wherein said electrically conductive structural element comprises a multilevel metal interconnection structure, and said film lies in contact with side walls and a top surface of at least a top level interconnection of said multilevel metal interconnection structure.

9. A semiconductor device having at least a multilevel metal interconnection structure, at least a capacitor which lies over said multilevel metal interconnection structure, and an inter-layer insulator under said capacitor and over said multilevel metal interconnection structure for isolating said multilevel metal interconnection structure form said capacitor,
wherein at least an anti-oxidizing film preventing penetration of oxygen is provided in said inter-layer insulator, so that said anti-oxidizing film lies covering the multilevel metal interconnection structure and under the capacitor.

10. The semiconductor device as claimed in claim 9, wherein the capacitor comprises a ferroelectric capacitor having a ferroelectric film.

11. The semiconductor device as claimed in claim 9, wherein the capacitor has a high dielectric film having a high dielectric constant.

12. The semiconductor device as claimed in claim 9, wherein said anti-oxidizing film lies over at least a top level interconnection of said multilevel metal interconnection structure.

13. The semiconductor device as claimed in claim 9, wherein said anti-oxidizing film lies in contact with side walls and a top surface of at least a top level interconnection of said multilevel metal interconnection structure.

14. A method of forming a semiconductor device comprising the steps of:
forming at least an electrically conductive structural element;
forming an inter-layer insulator over said electrically conductive structural element and said inter-layer insulator including at least a film preventing penetration of oxygen, and said film covering the electrically conductive structural element; and
forming at least a dielectric film which lies over said inter-layer insulator; and
carrying out a heat treatment in an oxygen-containing gas atmosphere.

15. The method as claimed in claim 14, wherein the dielectric film comprises a ferroelectric film.

16. The method as claimed in claim 15, wherein the ferroelectric film is of a ferroelectric capacitor.

17. The method as claimed in claim 14, wherein the dielectric film comprises a high dielectric film having a high dielectric constant.

18. The method as claimed in claim 17, wherein the high dielectric film is of a high dielectric capacitor.

19. The method as claimed in claim 14, wherein said film comprises an anti-oxidizing film.

20. The method as claimed in claim 14, wherein said electrically conductive structural element comprises a multilevel metal interconnection structure, and said film lies over at least a top level interconnection of said multilevel metal interconnection structure.

21. The method as claimed in claim 14, wherein said electrically conductive structural element comprises a multilevel metal interconnection structure, and said film lies in contact with side walls and a top surface of at least a top level interconnection of said multilevel metal interconnection structure.

22. A method of forming a semiconductor device comprising the steps of:
forming at least a multilevel metal interconnection structure;
forming an inter-layer insulator over said multilevel metal interconnection structure, and said inter-layer insulator including at least an anti-oxidizing film preventing penetration of oxygen and said anti-oxidizing film covering the multilevel metal interconnection structure;
forming at least a capacitor which lies over said multilevel metal interconnection structure; and
carrying out a heat treatment in an oxygen-containing gas atmosphere.

23. The method as claimed in claim 22, wherein the capacitor comprises a ferroelectric capacitor having a ferroelectric film.

24. The method as claimed in claim 22, wherein the capacitor has a high dielectric film having a high dielectric constant.

25. The method as claimed in claim 22, wherein said anti-oxidizing film lies over at least a top level interconnection of said multilevel metal interconnection structure.

26. The method as claimed in claim 22, wherein said anti-oxidizing film lies in contact with side walls and a top surface of at least a top level interconnection of said multilevel metal interconnection structure.
